(19) United States
(12) Patent Application Publication
(10) Pub. No.: US 2019/0173045 A1
(43) Pub. Date: Jun. 6, 2019

(54) ORGANIC LIGHT-EMITTING DEVICE

(71) Applicants: CHING-YAN CHAO, HSINCHU (TW); FENG-WEN YEN, TAIPEI (TW)

(72) Inventors: CHING-YAN CHAO, HSINCHU (TW); FENG-WEN YEN, TAIPEI (TW)

(73) Assignee: LUMINESCENCE TECHNOLOGY CORPORATION, HSINCHU (TW)

(21) Appl. No.: 15/922,924

(22) Filed: Mar. 16, 2018

(30) Foreign Application Priority Data
Mar. 21, 2017 (TW) 106109254
Sep. 1, 2017 (CN) 201710780921.8

(51) Int. Cl. H01L 51/52

(52) U.S. Cl. CPC H01L 51/5212; H01L 51/5209; H01L 2251/5392; H01L 2251/301; H01L 2251/308; H01L 2251/558

(57) ABSTRACT

An organic light-emitting device is provided, which may include a substrate, an auxiliary electrode, an insulation layer, a first electrode, an organic layer, and a second electrode. The auxiliary electrode is provided on the substrate, and the insulation layer is applied on a portion of the surface of auxiliary electrode, wherein the other portion of the surface of the auxiliary electrode not being covered by the insulation layer forms a first contact portion. The first electrode is disposed on the substrate, the insulation layer, and the first contact portion, and electrically connects the auxiliary electrode via the first contact portion. The organic layer is formed on the first electrode, and the second electrode is disposed on the organic layer. The first electrode will form an open loop zone adjacent to foreign objects (e.g. particles), so that the first electrode and second electrode will not be short-circuited because the second electrode contacts the foreign objects in the open loop zone during the manufacturing process.

### CROSS-REFERENCE TO RELATED APPLICATIONS

This application claims the benefit of priority of TW Patent Application Ser. No. 106109254 filed on Mar. 21, 2017, the content of which is incorporated herein by reference in its entirety.

### FIELD OF INVENTION

The present invention relates to a light-emitting device, in particular to an organic light-emitting device using the organic light-emitting material.

### BACKGROUND OF THE INVENTION

Existed organic light-emitting device comprises a substrate, an auxiliary electrode, an insulation layer, a first electrode (typically anode), an organic layer and a second electrode (typically cathode). Among them, the auxiliary electrode is electrically connected to the first electrode and the auxiliary electrodes are connected with each other; when powered, the impedance of the first electrode and voltage drop is decreased by way of the auxiliary electrode to allow the luminance uniformity of the organic light-emitting device to be improved.

Further, since the gap between the first electrode and the second electrode is small, the first electrode may contact with the second electrode to cause short circuit due to possible particles or other reasons even when the organic light-emitting device is processed in a clean room, furthermore, leading non-luminance of the entire organic light-emitting device or of most part, or a dead pixel with a luminance lower than average level. However, it is not suitable to increase the thickness of the organic layer between the first electrode and the second electrode for solving the problem of short circuit between the two electrodes.

For solving the above problems, many manufacturers and research institutions in related fields, such as LG Chem Co., LTD, LG Display Co., LTD, Industrial Technology Research Institute, etc., have proposed a variety of schemes, In particular, LG Chem Co., LTD and LG Display Co., LTD have owned at least the following patents: U.S. Pat. No. 9,035,420, CN106133939A, CN105164829A, and TWI552411. The solution of all of the above patents is to form a fuse pattern, the so-called anti-short-circuit layer, between the first electrode and the auxiliary electrodes in order to prevent the two electrodes from being seriously short-circuited without increasing the thickness of the organic layer.

However, arranging the fuse pattern or anti-short-circuit layer between the first electrode and the auxiliary electrode is accomplished only by using a special mask for additional fabricating steps of the process, which reduces the cost incurred by the increase of the thickness of the organic layer, but cause additional increase in manufacturing cost and time.

### SUMMARY OF THE INVENTION

In view of the above problems of the conventional technique, the present invention provides an organic light-emitting device to solve the problem of short circuit between the two electrodes without additional mask, manufacturing steps, and cost.

To achieve the foregoing objective, the present invention provides an organic light-emitting device, which may include a substrate, an auxiliary electrode, an insulation layer, a first electrode, an organic layer, and a second electrode. The auxiliary electrode is provided on the substrate. The insulation layer is applied on a portion of the surface of the auxiliary electrode, and the other portion of the surface of the auxiliary electrode not being covered by the insulation layer forms a first contact portion. The first electrode is disposed on the substrate, the insulation layer, and the first contact portion, and electrically connecting the auxiliary electrode via the first contact portion. The organic layer is formed on the first electrode, and the second electrode is disposed on the organic layer. In particular, a portion of the first electrode adjacent to the insulation layer or a foreign object forms an open loop zone and a portion of the second electrode adjacent to the foreign object couples to the open loop zone. Therefore, the first electrode forms an open circuit area around the dirt (such as: particles) and the insulation layer, and, when particles appear during the process, the second electrode connects the open loop zone so that the first electrode and the second electrode won't be short-circuited.

To achieve the foregoing objective, the present invention further provides an organic light-emitting device, which may include a substrate, an auxiliary electrode, an insulation layer, a first conductive layer, a first electrode, an organic layer, and a second electrode. The auxiliary electrode is provided on the substrate, and the insulation layer is applied on the surface of the auxiliary electrode. The first conductive layer is provided between the auxiliary electrode and the substrate. In particular, a peripheral portion of the first conductive layer not being covered by the insulation layer forms a second contact portion. The first electrode is disposed on the substrate, the insulation layer, and the second contact portion, and electrically connecting the auxiliary electrode via the second contact portion. An organic layer is formed on the first electrode, and a second electrode is disposed on the organic layer. A portion of the first electrode adjacent to the insulation layer or a foreign object forms an open loop zone and a portion of the second electrode adjacent to the foreign object couples to the open loop zone. Therefore, the first electrode forms an open circuit area around the dirt (such as: particles) and the insulation layer, and, when particles appear during the process, the second electrode connects the open loop zone so that the first electrode and the second electrode won't be short-circuited.

In one embodiment of the present invention, the first electrode of the organic light-emitting device is made of a metal or a conductive metal oxide, where the thickness of the first electrode is no more than 12 nm, and the work function of the first electrode is no less than at least 4.2 eV. Besides, the auxiliary electrode forms a grid pattern on the substrate.

To sum up, the present invention has one or more of the following advantages:

1. The reason why the first electrode can form an open loop zone adjacent to the insulation layer or foreign objects lies in that the rough portion of the first electrode protruding from the substrate tends to be discontinued in shape for the first electrode is quite thin. Therefore, the formation of the open loop zone does not need an additional mask.

2. As described above, the open loop zone can be formed by utilizing the surface topography of the first electrode adjacent to the insulation layer or foreign objects, so it is not necessary to form an additional fuse pattern or anti-short-circuit layer through additional manufacturing steps.

3. In one embodiment of the present invention, the organic light-emitting device further includes a first conductive layer between the auxiliary electrode and the substrate so as to connect the auxiliary electrode with the first electrode. The conventional organic light-emitting device already has such structure design, so the structure will not incur additional cost.

### BRIEF DESCRIPTION OF THE DRAWINGS

For a better understanding of the aforementioned embodiments of the invention as well as additional embodiments thereof, reference should be made to the Description of Embodiments below, in conjunction with the following drawings in which like reference numerals refer to corresponding parts throughout the figures.

FIG. 1 is a schematic view showing the layout of an organic light-emitting device in accordance with one embodiment of the present invention.

FIG. 2 is a cross-sectional view taken along the line A-A′ of FIG. 1.

FIG. 3 is a cross-sectional view taken along the line B-B′ of FIG. 1.

FIG. 4 is a schematic view showing the organic light-emitting device of FIG. 3 after the formation of the organic layer and the second electrode.

FIG. 5 is a schematic view showing the structure around the foreign object in accordance with one embodiment of the present invention.

FIG. 6 is a graph showing the transmittance of the organic light-emitting devices using Ag layers of different thicknesses as the first electrode, respectively, in accordance with one embodiment of the present invention.

FIG. 7 is a schematic view showing the layout of an organic light-emitting device in accordance with another embodiment of the present invention.

FIG. 8 is a cross-sectional view taken along the line C-C′ of FIG. 7.

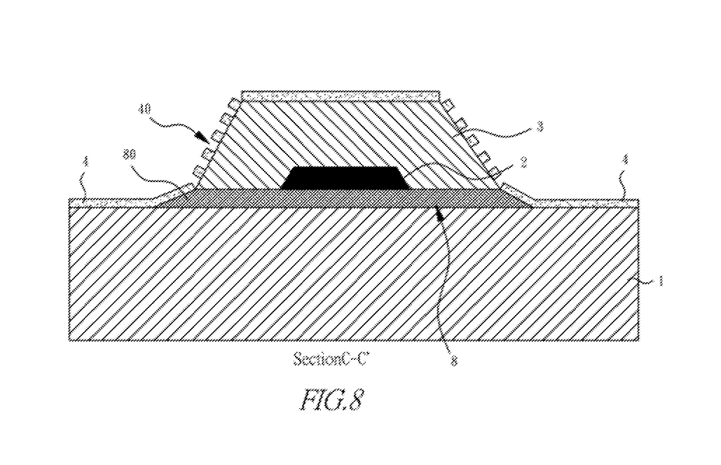

FIG. 9 is a schematic view showing the layout of an organic light-emitting device in accordance with still another embodiment of the present invention.

FIG. 10 is a cross-sectional view taken along the line D-D′ of FIG. 9.

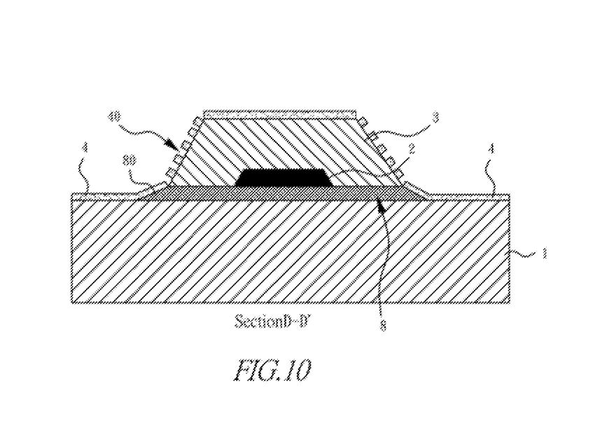

FIG. 11 is a cross-sectional view taken along the line E-E′ of FIG. 9.

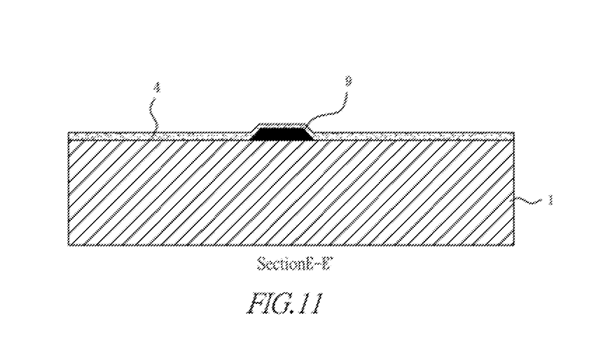

### DESCRIPTION OF THE PREFERRED EMBODIMENTS

The following description is about embodiments of the present invention; however, it is not intended to limit the scope of the present invention.

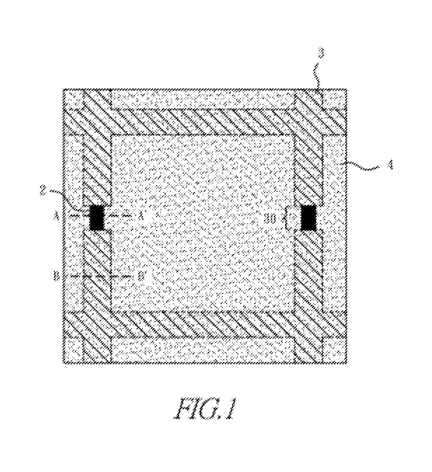

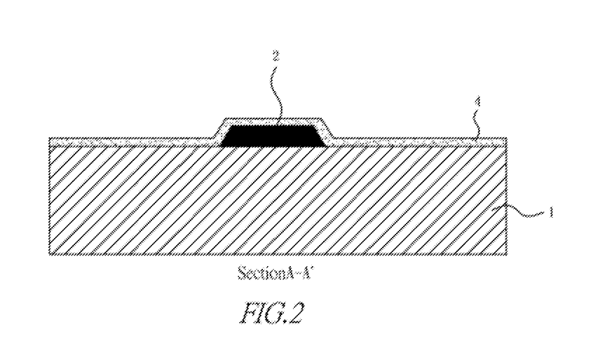

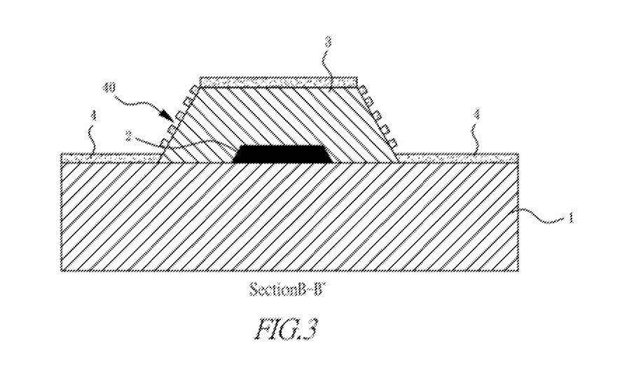

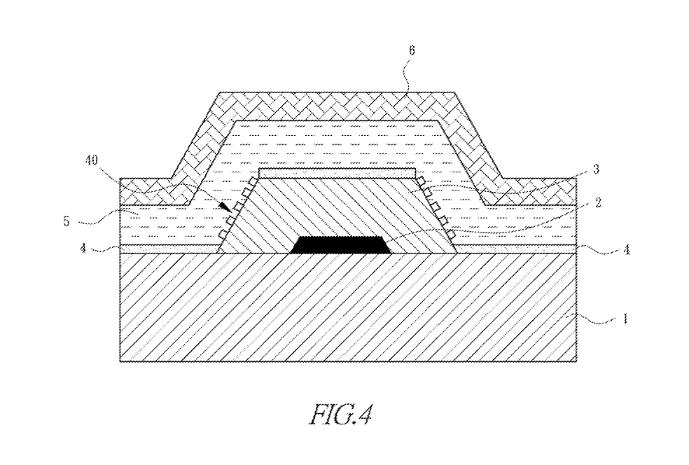

Please refer to FIGS. 1-4, which show an organic light-emitting device in accordance with one embodiment of the present invention. The organic light-emitting device includes a substrate 1, an auxiliary electrode 2, an insulation layer 3, a first electrode 4 (i.e. anode), an organic layer 5 and a second electrode 6 (i.e. cathode). The auxiliary electrode 2 is provided on the substrate 1, and the insulation layer 3 is applied on a portion of the surface of the auxiliary electrode 2, such that the other portion of the surface of the auxiliary electrode 2 not being covered by the insulation layer 3 forms a first contact portion 30. The first electrode 4 is disposed on the substrate 1, the insulation layer 3, and the first contact portion 30, and electrically connects the auxiliary electrode 2 via the first contact portion 30. The first electrode 4 includes an open loop zone 40 adjacent to the insulation layer 3 or the foreign object 7. The open loop zone 40 includes a rough portion of the first electrode 4 protruding from the surface of the substrate 1 near the insulation layer 3 or the foreign object 7. The organic layer 5 is formed on the first electrode 4, and the second electrode 6 is disposed on the organic layer 5.

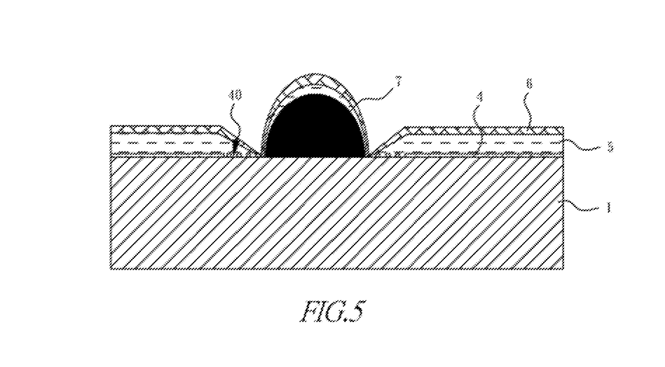

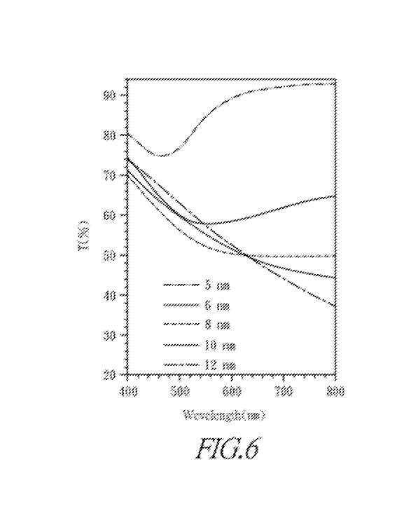

With reference to FIG. 5, the thickness of the first electrode 4 is usually no more than 12 nm. During the formation of the first electrode 4, the thickness of the portion of the first electrode 4 around the foreign object 7 decreases to form the open loop zone 40 due to the shadow effect incurred by the foreign object 7. During the process of the second electrode 6, the second electrode 6 connects to the open loop zone 40 to prevent a short circuit from forming between the first electrode 4 and the second electrode 6 due to the effects of the dirt so as to solve the problem of short circuit between the first electrode 4 and the second electrode 6. Compared with prior art, the present invention can effectively prevent short circuit without fuse pattern, so definitely has an inventive step. With reference to FIG. 6, which is a graph showing the transmittance of the organic light-emitting devices using Ag layers of different thicknesses (5 nm˜12 nm) as the first electrode 4, respectively. According to FIG. 6, it is obvious that as the thickness of the first electrode 4 decreases, the transmittance of the first electrode 4 will gradually increase. When the thickness of the first electrode 4 is no more than 10 nm, the transmittance thereof in wavelength of 550 nm can exceed 50%. When the thickness of the first electrode 4 is 6 nm, the transmittance thereof is about 58%. When the thickness of the first electrode 4 is 5 nm, the transmittance thereof is about 85%. The impedance of the first electrode 4 will significantly increase when the thickness further decreases, which will influence the characteristics of the produced product. In the embodiments of the present invention, though Ag is used as the first electrode 4, the present invention is not limited thereto in practical embodiments. The first electrode 4 of the present invention may also be made of metal or conductive metal oxide materials. Preferably, the metal is Ag, Al, Au, Be, Co, Ni, Cu, Ir or Pt, and the conductive metal oxide is indium tin oxide (ITO), indium zinc oxide (IZO), or aluminum zinc oxide (AZO).

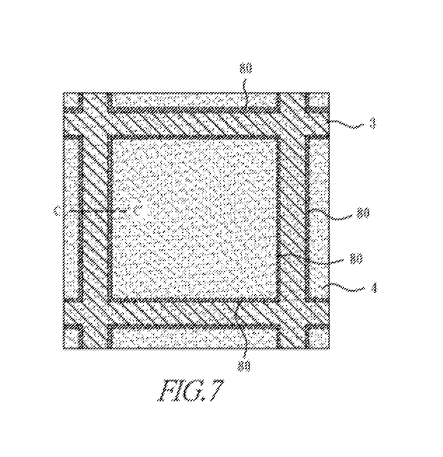

With reference to FIG. 7, which is a schematic view showing the layout of the organic light-emitting device in accordance with another embodiment of the present invention. The organic light-emitting device of the embodiment is similar to that of the previous embodiment, except that the auxiliary electrode 2 is completely covered by the insulation layer 3. Besides, a first conductive layer 8 is provided between the auxiliary electrode 2 and the substrate 1, and the peripheral portion of the first conductive layer 8 not being covered by the insulation layer 3 forms the second contact portion 80. The first electrode 4 is disposed on the substrate 1, the insulation layer 3, and the second contact portion 80, and electrically connects the auxiliary electrode 2 via the second contact portion 80. Further, the first electrode 4 includes an open loop zone 40 adjacent to the insulation layer 3 or foreign objects 7. The organic layer 5 is formed on the first electrode 4, and the second electrode 6 is disposed on the organic layer 5. The thickness of the first electrode 4 is usually no more than 12 nm. During the formation of the first electrode 4, the thickness of the portion of the first electrode 4 around the foreign object 7 decreases to form the open loop zone 40 due to the shadow effect incurred by the foreign objects 7. During the manufacturing process, the portion of the second electrode 6 around the foreign object 7 connects to the open loop zone 40, such that the first electrode 4 and the second electrode 6 will not be short-circuited.

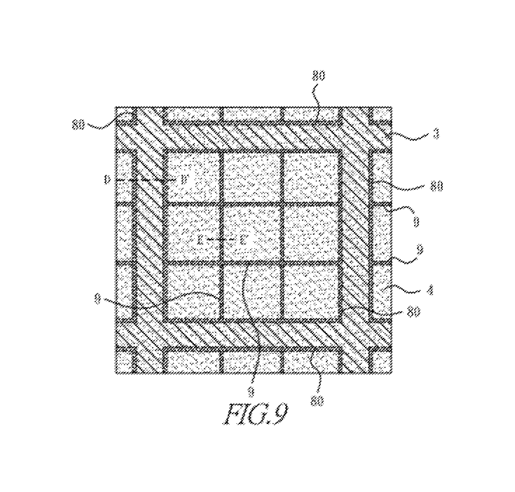

In above embodiments, the thickness of the first electrode 4 is no more than 12 nm, or further no more than 10 nm. Preferably, the thickness of the first electrode 4 is no more than 8 nm, or further no more than 6 nm in another preferred embodiment. In addition, the work function of the first electrode 4 is no less than 4.2 eV, preferably no less than 4.6 eV, and most preferably no less than 5.0 eV. In above embodiments, the open loop zone 40 further comprises a rough portion of the first electrode protruding from a surface of the substrate 1 near the insulation layer 3 or the foreign object 7. In particular, the auxiliary electrode 2 forms a grid pattern on the substrate 1 (as shown in FIGS. 1, 7 and 9). Moreover, the organic light-emitting device may further include a second conductive layer 9 formed between the first electrode 4 and the substrate 1 for properly adjusting the impedance of the first electrode 4, the auxiliary electrode 2, and the first conductive layer 8. As shown in FIG. 9, the second conductive layer 9 is formed between the first electrode 4 and the substrate 1 such that the second conductive layer 9 forms a subgrid pattern in each grid of the grid pattern of the auxiliary electrode 2. In an embodiment, the first conductive layer 8 and the second conductive layer 9 may be made of conductive metal oxide, such as: ITO, IZO or AZO.

From the above embodiments, it can be observed that the problem of short circuit between the first electrode and the second electrode can be solved.

The above disclosure is related to the detailed technical contents and inventive features thereof. Those skilled in the art may make a variety of modifications and replacements based on the disclosures and suggestions of the invention as described without departing from the spirit thereof. Although such modifications and replacements are not fully disclosed in the above descriptions, they have substantially been covered by the following claims.

What is claimed is:

1. An organic light-emitting device, comprising:
a substrate;
an auxiliary electrode provided on the substrate;
an insulation layer applied on a portion of a surface of the auxiliary electrode, wherein the other portion of the surface of the auxiliary electrode not being covered by the insulation layer forms a first contact portion;
a first electrode disposed on the substrate, the insulation layer, and the first contact portion, and electrically connecting the auxiliary electrode via the first contact portion, wherein a thickness of the first electrode is no more than 12 nm;
an organic layer formed on the first electrode; and
a second electrode disposed on the organic layer.

2. The organic light-emitting device according to claim 1, wherein a portion of the first electrode adjacent to the insulation layer or a foreign object forms an open loop zone and a portion of the second electrode adjacent to the foreign object connects the open loop zone.

3. The organic light-emitting device according to claim 2, wherein the open loop zone further comprises a rough portion of the first electrode protruding from a surface of the substrate near the insulation layer or the foreign object.

4. The organic light-emitting device according to claim 1, wherein the first electrode is a metal or a conductive metal oxide.

5. The organic light-emitting device according to claim 4, wherein the metal is Ag, Al, Au, Be, Co, Ni, Cu, Ir or Pt.

6. The organic light-emitting device according to claim 4, wherein the conductive metal oxide is indium tin oxide (ITO), indium zinc oxide (IZO), or aluminum zinc oxide (AZO).

7. The organic light-emitting device according to claim 1, wherein the thickness of the first electrode is no more than 10 nm.

8. The organic light-emitting device according to claim 1, wherein the thickness of the first electrode is no more than 8 nm.

9. The organic light-emitting device according to claim 1, wherein a work function of the first electrode is no less than 4.2 eV.

10. An organic light-emitting device, comprising:
a substrate;
an auxiliary electrode provided on the substrate;
an insulation layer applied on a surface of the auxiliary electrode;
a first conductive layer provided between the auxiliary electrode and the substrate, wherein a peripheral portion of the first conductive layer not being covered by the insulation layer forms a second contact portion;
a first electrode disposed on the substrate, the insulation layer, and the second contact portion, and electrically connecting the auxiliary electrode via the second contact portion, wherein a thickness of the first electrode is no more than 12 nm;
an organic layer formed on the first electrode; and
a second electrode disposed on the organic layer.

11. The organic light-emitting device according to claim 10, wherein a portion of the first electrode adjacent to the insulation layer or a foreign object forms an open loop zone and a portion of the second electrode adjacent to the foreign object connects the open loop zone.

12. The organic light-emitting device according to claim 10, wherein the auxiliary electrode forms a grid pattern on the substrate.

13. The organic light-emitting device according to claim 12, further comprising a second conductive layer formed between the first electrode and the substrate, wherein the second conductive layer forms a subgrid pattern in each grid of the grid pattern.

14. The organic light-emitting device according to claim 11, wherein the open loop zone further comprises a rough portion of the first electrode protruding from a surface of the substrate near the insulation layer or the foreign object.

15. The organic light-emitting device according to claim 10, wherein the first electrode is a metal or a conductive metal oxide.

16. The organic light-emitting device according to claim 15, wherein the metal is Ag, Al, Au, Be, Co, Ni, Cu, Ir or Pt.

17. The organic light-emitting device according to claim 15, wherein the conductive metal oxide is indium tin oxide (ITO), indium zinc oxide (IZO), or aluminum zinc oxide (AZO).

18. The organic light-emitting device according to claim 10, wherein the thickness of the first electrode is no more than 10 nm.

19. The organic light-emitting device according to claim 10, wherein the thickness of the first electrode is no more than 8 nm.

20. The organic light-emitting device according to claim 10, wherein a work function of the first electrode is no less than 4.2 eV.
